(19) United States
(12) Patent Application Publication
(10) Pub. No.: US 2021/0273773 A1
(43) Pub. Date: Sep. 2, 2021

(54) METHODS AND APPARATUS FOR IN-BAND FULL-DUPLEX TRANSCEIVER WITH BI-DIRECTIONAL FREQUENCY CONVERTER

(71) Applicant: Massachusetts Institute of Technology, Cambridge, MA (US)

(72) Inventors: Xiang YI, Cambridge, MA (US); Kenneth E. KOLODZIEJ, Lexington, MA (US); Ruonan HAN, Winchester, MA (US)

(21) Appl. No.: 17/185,142

(22) Filed: Feb. 25, 2021

Related U.S. Application Data
(60) Provisional application No. 62/984,136, filed on Mar. 2, 2020.

(51) Int. Cl. H04L 5/14; H04B 1/56

(52) U.S. Cl. CPC H04L 5/1461; H04B 1/56

(57) ABSTRACT

A transceiver system is configured to concurrently send TX signals and receive RX signals on an antenna system in the same frequency band. A bi-directional frequency converter circuit modulates the TX signals and RX signals by a modulation frequency. The modulated TX signals and RX are frequency shifted so that they have different frequencies that are not in the same frequency band. For example, the TX signal may be shifted to a higher frequency and the RX signal may be shifted to a lower frequency. Filters can then be used to isolate the TX signal and the RX signal for transmission and/or processing.

### RELATED APPLICATIONS

This patent claims priority to and benefit of U.S. Provisional Patent Application No. 62/984,136 (filed Mar. 2, 2020), which is incorporated herein by reference.

### STATEMENT REGARDING FEDERAL FUNDING

This invention was made with government support under grant number FA8702-15-D-0001 awarded by the U.S. Air Force. The U.S. government has certain rights in the invention.

### FIELD

This patent relates to using frequency shifting to reduce signal interference of electromagnetic signals in a network and/or communication system.

### BACKGROUND

Many radio frequency (RF) transmit and receive systems may operate in one or more of a variety of modes such as a time division duplex (TDD) mode, frequency division duplex mode (FDD) and in-band full-duplex (IBFD) mode. Increasing demands on the wireless communication and sensing have been driving the development of RF systems in increasingly crowded frequency spectrums. Since RF systems operating in the IBFD mode concurrently or simultaneously transmit and review signals at the same frequency, compared with half-duplex modes such as TDD and FDD, use of the IBFD mode significantly increases the spectrum capacity and simplifies the transmission protocol. Nonreciprocal electronic devices, such as isolators, gyrators, and circulators, are often required for full-duplex applications including but not limited to, wireless communication, radar, and quantum signal processing.

Conventional ferrite circulators, based on Faraday rotation, are bulky due to inclusion of a bulk magnet and cannot be integrated on a chip. Magnet-free circulators have become attractive due to their compact size and compatibility with CMOS integrated circuit technologies. Usually they use time variance devices, such as switches driven by the modulation signal, to break the Lorentz reciprocity and implement phase nonreciprocity. N-path filter-based circulators have been proposed to realize the phase nonreciprocity, but they are not practical at higher frequencies since they require the use of multiphase non-overlapping clocks.

Another typical architecture utilizes a switched transmission line or delay line-based circulator. While such architectures are useful for higher frequencies, their on-chip area is large for low frequencies. What is more, the common problems of these integrated magnet-free circulators are that the isolation is limited, and the isolation bandwidth is narrow. There are two main reasons which are both due to the phase nonreciprocity concept of these circulators. The first reason is on-chip coupling. Because the operation frequencies of the transmitter (TX) port and the receiver (RX) port are the same, the signal leaks from TX port to RX port through various paths, including substrate coupling, magnetic coupling, and even power line coupling. The second reason is that the isolation of these circulators mainly relies on the signal cancellation of two paths, which means the amplitude and phase mismatches are small only within a narrow bandwidth. Thus, a new concept to achieve high isolation with large isolation bandwidth is desired.

### SUMMARY

A fully integrated bi-directional frequency converter (BDFC) integrated into a network system may solve many of the problems above. Driven by a modulation signal, one port may be connected to a shared antenna (ANT), and another port may be connected to both transmit (TX) and receive (RX) through respective ones of high-pass and low-pass filters. For reasons which will become apparent from the description below, the counterintuitive fact is that, in the BDFC described herein, the signal frequency is shifted to only one direction in spite of the signal direction. Thus, the transmitter-to-antenna signal path either (TX-ANT) or the antenna-to-receiver signal path (ANT-RX) experiences the frequency down-conversion.

With this approach, the BDFC provides high amount of isolation over more than one GHz of bandwidth. Additionally, the BDFC incorporates frequency conversion, which helps eliminate components within the receiver and reduces (and ideally minimizes) the overall power consumption of the BDFC. These enhancements may be beneficial when incorporated into a 5G or 6G wireless framework by using a flexible duplex mode currently included in the specifications for those frameworks. IBFD operation helps alleviate the increasing demand for frequency spectrum access by allowing twice the number of wireless users to occupy any given frequency band. This can drastically change many existing wireless network architectures, which currently operate in half-duplex mode.

In embodiments, a transceiver system includes an antenna and a transmit/receive (TX/RX) circuit configured to couple transmit (TX) signals for transmission to the antenna and receive incoming (RX) signals from the antenna. Transmission of the TX signals and reception of the RX signals occurs concurrently within a single frequency band. A bidirectional frequency converter (BDFC) circuit is included to separate the TX signals from the RX signals by converting the frequency of the TX signals, the RX signals, or both.

The BDFC circuit may be configured to shift the frequency of the RX signal in one direction in a frequency spectrum and shift the frequency of the TX signal in another direction in the frequency spectrum.

The frequency converter circuit may be configured to shift the frequency of the RX signal to a relatively lower frequency and shift the frequency of the TX signal a relatively higher frequency.

A first filter may be included to filter the TX signals and a second filter may be included to filter the RX signals.

The BDFC circuit may include a plurality of parallel signal paths. In embodiments, the BDFC circuit includes four signal paths.

At least one of the plurality of parallel signal paths may include a phase shift circuit.

At least one of the plurality of parallel signal paths may include a switch for modulating the TX signal and/or modulating the RX signal.

Multiple paths of the plurality of parallel signal paths may include a phase shift circuit and each phase shift circuit may be configured to shift the phase of the TX signal and/or the RX signal by a different degree value.

The plurality of parallel signal paths may be differential signal paths.

At least one of the plurality of parallel signal paths may include a differential modulation switch and a differential phase shift circuit.

In another embodiment, a transceiver system includes an antenna and a transmit/receive (TX/RX) circuit configured to couple transmit (TX) signals for transmission to the antenna and receive incoming (RX) signals from the antenna. Transmission of the TX signals and reception of the RX signals occurs concurrently within a single frequency band. A bidirectional frequency converter (BDFC) circuit having is included. The BDFC circuit includes one or more signal paths that convert a frequency of the TX signals to a first frequency and convert a frequency of the RX signals second frequency. The first frequency and the second frequency are in separate frequency bands; The BDFC also includes a first port coupled to the antenna and configured to receive the RX signals and transmit the TX signals within the single frequency band, and a second port coupled to the message circuit to receive the TX signals having the first frequency from the message circuit and transmit the RX signals having the second frequency to the messaging circuit.

The BDFC circuit may be configured to shift the frequency of the RX signal to a relatively lower frequency in a frequency spectrum and shift the frequency of the TX signal a relatively higher frequency in the frequency spectrum.

A first filter may be included to pass the TX signals having the first frequency, and a second filter may be included to pass the RX signals having the second frequency.

The BDFC circuit may include four signal paths.

At least one of the parallel signal paths may include a phase shift circuit.

At least one of the plurality of parallel signal paths may include a switch for modulating the TX signal and/or modulating the RX signal.

The one or more parallel signal paths may be differential signal paths.

At least one of the plurality of parallel signal paths may include a differential modulation switch and a differential phase shift circuit.

In another embodiment, a transceiver system includes an antenna and a transmit/receive (TX/RX) circuit configured to couple transmit (TX) signals for transmission to the antenna and receive incoming (RX) signals from the antenna. Transmission of the TX signals and reception of the RX signals occurs concurrently within a single frequency band. The transceiver system also includes means for modulating the TX signal and the RX signal by a modulation frequency and means for shifting a frequency of the TX signal to a first frequency and shifting the RX signal to a second frequency, wherein the first and second frequencies are in different frequency bands.

### BRIEF DESCRIPTION OF THE DRAWINGS

The foregoing features may be more fully understood from the following description of the drawings. The drawings aid in explaining and understanding the disclosed technology. Since it is often impractical or impossible to illustrate and describe every possible embodiment, the provided figures depict one or more exemplary embodiments. Accordingly, the figures are not intended to limit the scope of the invention. Like numbers in the figures denote like elements.

FIG. 1 is a block diagram of a radio frequency (RF) system for transmitting and receiving signals at the substantially at substantially the same time and in the same frequency band or at the same frequency.

FIG. 2 is a block diagram of an RF system including a prior art circulator circuit.

FIG. 3 is a block diagram of an RF system including a bi-directional frequency converter circuit.

FIG. 4 is a circuit diagram of an RF system illustrating multiple signal paths of a bidirectional frequency converter circuit which may be the same as or similar to the bi-directional frequency converter circuit of FIG. 3.

FIG. 5 is a circuit diagram of an RF system having a bi-directional frequency converter circuit having differential signal paths.

FIG. 6 is a series of phase vector diagrams (phasor diagrams) showing conversion of a transmit (TX) signal prior to transmission.

FIG. 7 is a series of phasor diagrams showing conversion of a receive (RX) signal after it is received.

### DETAILED DESCRIPTION

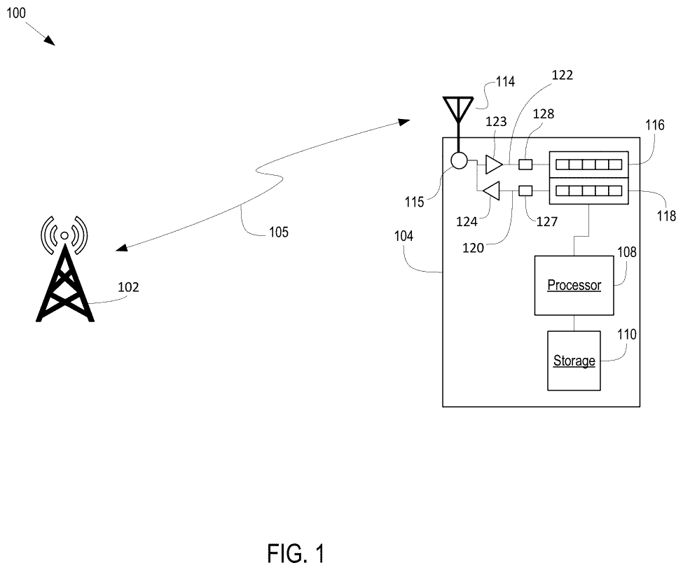

Referring to FIG. 1, an example network 100 includes a base station 102 and mobile device 104 in communication through a wireless link 105. Network 100 may be an in-band full-duplex (IBFD), also known as a same-frequency simultaneous transmit and receive (STAR) system, where a base station 102 and/or mobile device 104 each transmit and receive data (i.e. messages) on the same frequency band (or at the same frequency) at the same time. For example, messages sent by base station 102 may be sent in the same frequency band at the same time as messages received by the base station 102. Likewise, messages sent by the mobile device 104 may be sent in the same frequency band at the same time as messages received by the mobile device 104.

Network 100 may be any type of communication network that utilizes in-band full-duplex transmission. Although depicted as a wireless communication network in FIG. 1, network 100 could also by a satellite network, a radar network, a wired network, etc. One skilled in the art will recognize that the systems and methods described here can be used, or can be adapted to be used, with any type of network including those that employ in-band full-duplex technologies.

In FIG. 1, for ease of illustration, details of mobile device 104 are shown to illustrate and discuss the technology. However, the systems and methods described in this patent can be included as part of base station 102, of mobile transceivers, or of any device utilizing in-band full-duplex transmission or otherwise subject to signal interference between transmitter and receiver channels. Wireless networks have been designed to cover large areas with static access points and symmetric communications that utilized spectrally inefficient frequency division duplexing for channel access. The trend has been towards deploying significantly smaller cells that utilize time-division duplexing to support asymmetric data traffic for user equipment, such as large file downloads and high-definition video streaming applications that are common on mobile devices. The systems and methods described in this patent are suitable for use in any device operating in any such network.

Mobile device 104 may include an antenna system 114 comprising one or more antennas (e.g. a bistatic or monostatic antenna system) for transmission and reception of messages over the wireless link 105. In some embodiments, the antenna system 114 is a single antenna that is used for both transmission and reception of signals.

To isolate incoming and outgoing messages, mobile device 104 may include a bi-directional frequency converter 115 which converts the frequencies of outgoing and incoming messages. couples the antenna to transmit and receive systems (e.g. a transceiver) of mobile device 104. The bi-directional frequency converter 115 circulator is coupled between the antenna port and the transmitter and receiver ports to direct transmission signals (e.g. signals generated by a transmitter) to the antenna, and direct signals received by the antenna to a receiver.

In other embodiments, the antenna system 114 may include two or more antennas (e.g. separate receive and transmit antennas). In embodiments a receive antenna system may comprise one or more antennas and a transmit antenna system may comprise one or more antennas). In this case, although a system may use separate transmit and receive antennas, the antennas may be located close enough together (e.g. physically located in the same device or on the same antenna tower) so that the receive antenna(s) receive transmissions (e.g. RF signals) being emitted via the transmit antenna.

The mobile device 104 includes a processor 108 configured to (among other things) execute the transmit and receive operations of the mobile device 104. The processor 108 includes a memory and may be coupled to volatile or non-volatile storage 110. The memory and/or storage hold software instructions that can be executed by the processor 108. The software instructions may also cause the processor to run the network functions of mobile device 104 such as sending data to transmission buffer 118 or receiving data from receive buffer 116. In general, processor 108 may be programmed to perform some or all the functions described in this patent. In embodiments, processor 108 may be a single processor that performs the functions or may comprise multiple processors each programmed to perform one or some of the functions.

Transmit signal path 120 may comprise buffer 118, digital-to-analog converter (DAC) 127, transmit amplifier 124 and other circuitry such as and a modulator to modulate the frequency TX signal to a modulated frequency (such as a frequency ω₀+ω_{M}), as discussed below. These circuits are not explicitly shown in FIG. 1 for ease of illustration. Thus, it should be appreciated that the TX signal path may comprise both digital and analog portions (i.e. digital signals propagate in some portions of the TX signal path and analog signals propagate in some portions of the TX signal path). For example, digital signals propagate in those portions of the transmit signal path between buffer 118 and the input of DAC 127 while analog signals propagate in those portions of transmit signal path 120 between the output of DAC 127 and antenna 114.

Similarly, receive signal path 122 may comprise amplifier 123, analog-to-digital converter (ADC) 128, buffer 116, a demodulator circuit to demodulate the RX signal, and other circuitry not explicitly shown in FIG. 1 for the reasons explained above. Thus, receive signal path 122 may comprise both digital and analog portions (i.e. analog signals propagate in some portions of the receive signal path 122 and digital signals propagate in some portions of the receive signal path 122). For example, analog signals propagate in those portions of receive signal path 122 from antenna 114 and the input of ADC 128 while digital signals propagate in those portions of receive signal path 122 the output of ADC 122 and buffer 116.

Also, in systems which include one antenna (such as that shown in FIG. 1), antenna 114 may be considered part of both the transmit and receive signal paths.

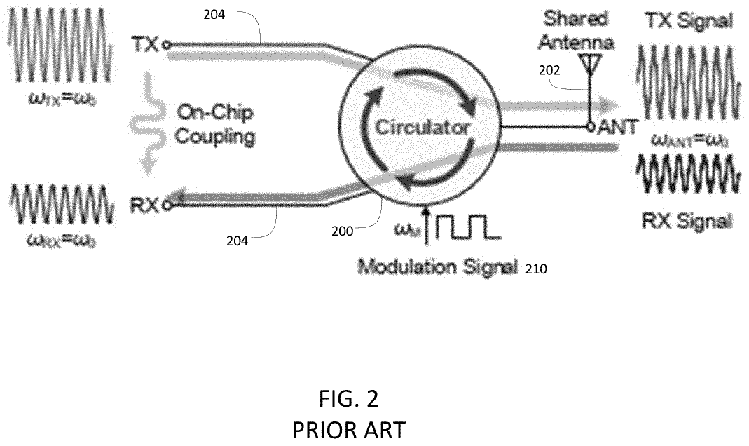

Referring to FIG. 2, a three-port circulator 200 of the prior art is configured to route incoming transmissions from a shared antenna 202 to the a received signal path (RX Path) 204 and route outgoing transmissions from a transmit signal path (TX Path) 206 to the shared antenna 202 As described above, the incoming and outgoing transmissions may be transmitted and received over the shared antenna 202 at the same time. The circulator 200 may be driven by modulation signal 210 having a modulation frequency Wm. Signals at the transit frequency ω_{TX} will be routed from the TX signal path 204 through circulator 200 to the antenna 202, and signals at the receive frequency ω_{RX} will be routed from the antenna 202 through circulator 200 to the RX receive signal path 204.

Disadvantages to using a circulator 200 include on chip-coupling between the TX and RX signal paths due, at least in part, to imperfect isolation between transmit, receive and antennas parts of the circular as well as due to imperfect impedance matches between the circulator parts and respective ones of the transmit, receive and antenna signal paths coupled thereto. The signals propagating on the TX and RX signal paths can interfere with each other because they are transmitted and received on the same antenna, at the same time, within the same frequency range or at the same frequency. Thus, systems that use circulators often employ signal cancellation techniques like those described in U.S. patent application Ser. No. 17/109,634 (filed Dec. 2, 2020) and U.S. Provisional Patent Application No. 63/019,694 (filed May 4, 2020). Of course, those cancellation techniques could also be used in conjunction with a bi-directional frequency converter described below.

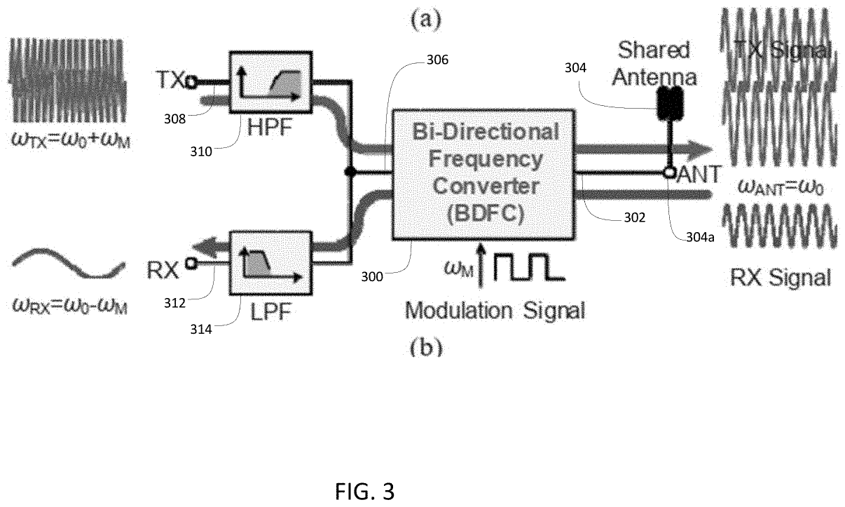

Referring to FIG. 3, a mobile device (such as mobile device 104 described above) may include a bi-directional frequency converter (BDFC) circuit 300 (sometimes refers to herein simply as a “BDFC”). BDFC 300 may be the same as or similar to BDFC 115 in FIG. 1. In this example embodiment, BDFC 300 can be driven by a modulation signal having a frequency ω_{M}. In embodiments, the modulation signal is connected to and drives the switches. For example, if the switches are implemented as field-effect transistors, the modulation signal may be coupled to the gate terminals of the transistors so that the switches turn on and off at the modulation frequency.

As shown in FIG. 3, BDFC 300 has a first port 302 coupled to a shared antenna 304 and a second port 306 coupled to the TX and RX signal paths. In other embodiments, BDFC 300 may have multiple antenna ports 302 which may be coupled to respective ones of multiple antennas (e.g. as in MIMO system). In embodiments, BDFC may comprise of multiple RX ports and/or multiple TX ports. In embodiments BDFC may comprise multiple RX parts, multiple TX ports and multiple antenna parts. Also, in another embodiment, BDFC 300 may have one (or more) TX ports coupled to a single TX signed path or with each TX port configured to be coupled to separate transmit signal paths. In embodiments, BDFC 300 may have one or more RX ports coupled to a single RX signal path or with each RX port configured to be coupled to separate receive signal paths. However, for ease of illustration, the examples described will be directed toward a two-port BDFC, as shown.

Unlike the circulator shown in FIG. 2, BDFC 300 operates so that, although the TX and RX frequencies are identical at the antenna port 304a, the frequencies of the TX and RX signals are split at the TX/RX port 306. In this example, the frequencies are split by a factor of about 2ω_{M} at the TX/RX port, where ω_{M} is the frequency of the BDFC modulation signal. Because the frequencies of the TX and RX signals are converted and split. Thus, in this example embodiment, the TX signal 308 can be isolated by a high pass filter 310 disposed in the transmit signal path and the RX signal can be isolated by a low pass filter 314 disposed in the receive signal path. The high-pass filter 310 may reject the low-frequency RX signal and the low-pass filter may reject the high frequency TX signal on the common mode TX/RX port 306. Additionally, the high-pass filter 310 may reject the low-frequency RX signal and the low-pass filter may reject the high frequency TX signal on other common mode nodes. For example, in some architectures, port 308 may be a common mode port that carries both the TX and RX signals. In this case, the high pass filter 310 may reject the low-frequency RX signal from the port 308.

In this example, the frequency of the TX signal 308 ω_{TX} is converted up to a frequency ω₀+ω_{M} and the frequency of the RX signal ω_{RX} is converted down to a frequency of ω₀−ω_{M}. In other embodiments, the signals may be modulated to different frequencies. For example, the RX signal may be shifted up and the TX signal may be shifted down. In this case, the filters may be switched so that the low-pass filter is coupled to the TX line and the high-pass filter is coupled to the RX-line, so that the low-pass filter passes the low-frequency TX signal and rejects the higher-frequency RX signal, and the high-pass filter passes the high-frequency RX signal and rejects the low-frequency TX signal.

In an alternate embodiment, the frequency of the TX signal 308 may be converted down and the frequency of the RX signal may be converted up. In this case, a low-pass filter may be used to isolate the TX signal and a high pass filter may be used to isolate the RX signal. Or, in other embodiments, both signals may be shifted up or down, as long as there is a frequency difference between the signals so that the signals can be isolated by filtering or other techniques.

Signal paths 406a-d have corresponding phase shift circuits 408a-d and switches 410a-d Phase shift circuits 408a and 408b on the TX signal paths 406a and 406b are configured to shift the phase of signals provided thereto by 0° and 90°, respectively. Similarly, the phase shift circuits 408c and 408d are configured to shift the phase of signals provided thereto by 180° and 270°, respectively. The phase shifts may be 90° relative phase shifts. So, for example, in other embodiments the phase shift circuits 408a-d may shift the signals by 10°, 100°, 190°, and 280°, respectively. In other embodiments, the phase shift circuits 408a-d may shift the signals by 10°, 100°, 170°, and 270°, respectively, or by any other relative phase shifts that allow for modulation, frequency conversion, and/or isolation of the TX and RX signals.

The switches 410a-d are configured to selectively couple the phase shifted signal to the TX/RX port 404 in response to the modulation signals 412. That is, in response to control signals provided thereto, the switches are selectively opened (i.e. provide a high impedance or high attenuation signal path between the first and second ports thereof) or closed (i.e. provide a low impedance or low attenuation signal path between the first and second ports). As a result of the phase shifting and switching operation, the TX and RX signals at the TX/RX port 404 are modulated so they occupy non-overlapping frequency bands. Thus, the TX and RX signals can be separated by filtering the signal at the TX/RX port so there is little, if any, signal interference between the TX and RX signals within mobile device 104. Similarly, the phase and shifting operation causes the TX signal to be shifted to the ω_{ANT} frequency so that it can be transmitted by the IBFD system at the correct frequency.

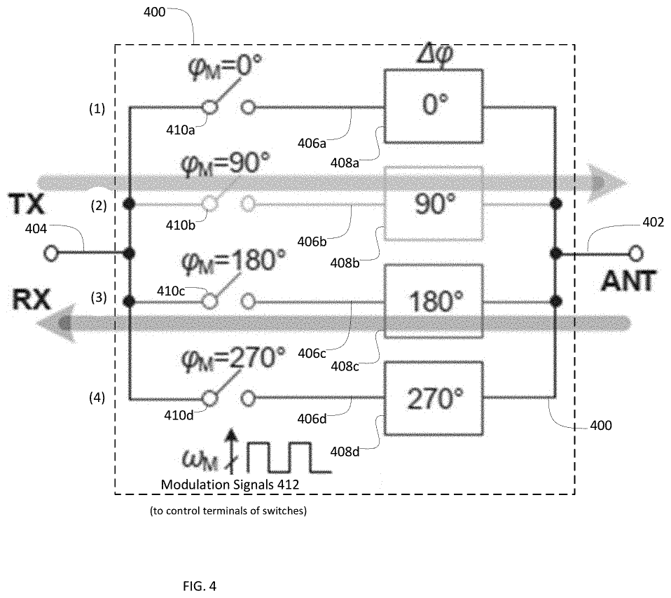

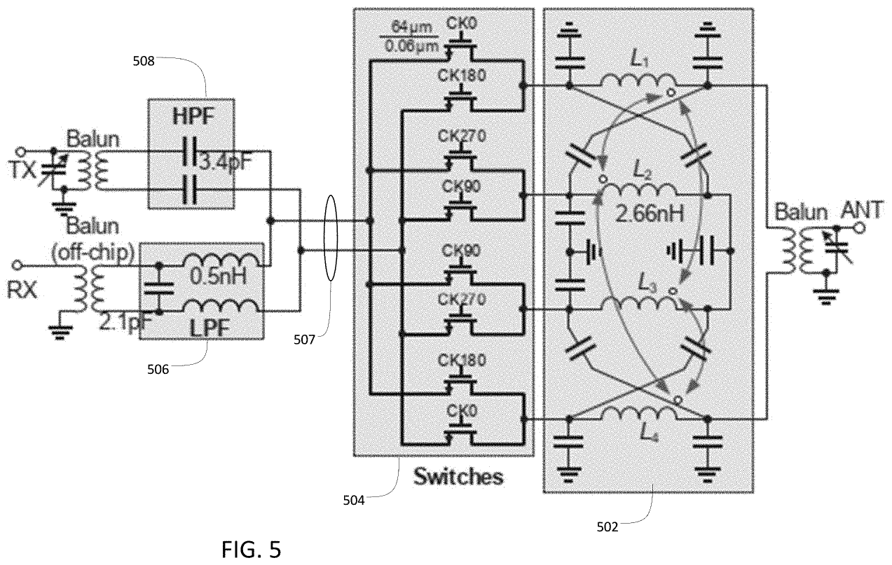

Turning to FIG. 5, the schematic diagram illustrates circuitry used in an example embodiment of a BDFC 500, which may be the same as or similar to the BDFC 300, 400 described in conjunction with FIG. 3 and FIG. 4 respectively. In this example embodiment, a lumped element Lange quadrature coupler is included to provide phase shifting of the signals. A switch block 504 includes differential switches for modulating the phase shifted signal to provide improved impedance matching, (e.g. as shown in FIG. 4. As described above, the differential switches may be driven by the switch modulation signals.

A high pass filter 508 (shown with series capacitors) is coupled to the differential TX/RX port 507 to isolate the TX signal. An LC low-pass filter 506 is also coupled to the TX/RX port to isolate the RX signal. Of course, other filter designs can be used as long as the filters can isolate the TX and RX signals. In certain embodiments, baluns may be included on the TX, RX, and antenna ports as shown in FIG. 5. However, other designs may exclude the baluns. In particular, the baluns may be useful for testing or for other situations where it is useful to isolate the bi-directional frequency converter circuit.

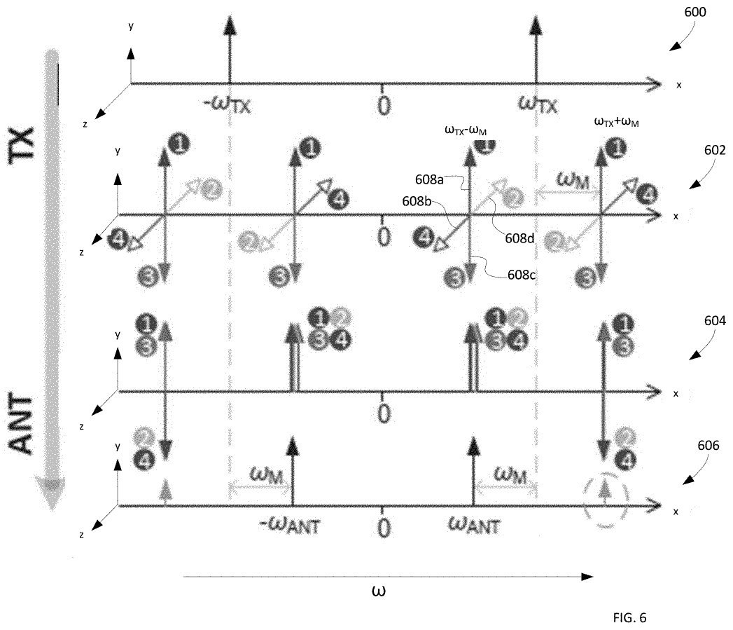

Referring to FIG. 6, phase vector (i.e. phasor) diagrams 600, 602, 604, and 606 are shown having an x-axis representing frequency, a y-axis representing the real portion of the phasors, and a z-axis representing the imaginary portion of the phasors. This diagram illustrates operation of a transmit signal propagating from the TX/RX signal 404, through BDFC 400, to the antenna port 402 (see FIG. 4). For simplicity, only the positive frequency components are discussed. However, one skilled in the art will recognize that the discussion can also apply to the negative frequency components of the signals by changing the appropriate signs.

In the first stage, i.e. plot 600, the TX signal is shown as having a frequency of ω_{TX} and a phase of 0°. In the second stage, i.e. plot 602, the TX signal is modulated by the switches 408a-d with a frequency of ϕ_{M}. Modulation by switch 408a along the signal path 406a where ϕ_{M}=0° produces the positive y-axis vertical phasor component (e.g. arrow 608a); modulation by switch 408b along the signal path 406b produces the positive z axis phasor component (e.g. arrow 608b); modulation by switch 408c along the signal path 406b produces the negative y-axis phasor component (e.g. arrow 608c); and modulation by switch 408d along the signal path 406d produces the negative z axis phasor component (e.g. arrow 608d).

The modulation also causes the signal to be shifted to frequency components: ω_{TX}−ω_{M} and ω_{TX}+ω_{M}. In the next stage, i.e. plot 604, a band pass filter (not shown in the figures) placed at the antenna port (e.g. antenna port 402) rejects the frequency component ω_{TX}+ω_{M} and allows the frequency component ω_{TX}−ω_{M} to pass through.

After filtering, the TX signal flows through the phase shift circuits 498a-d so that, at the next stage in plot 606, the signals are combined to form the transmission signal that is transmitted by the antenna 402.

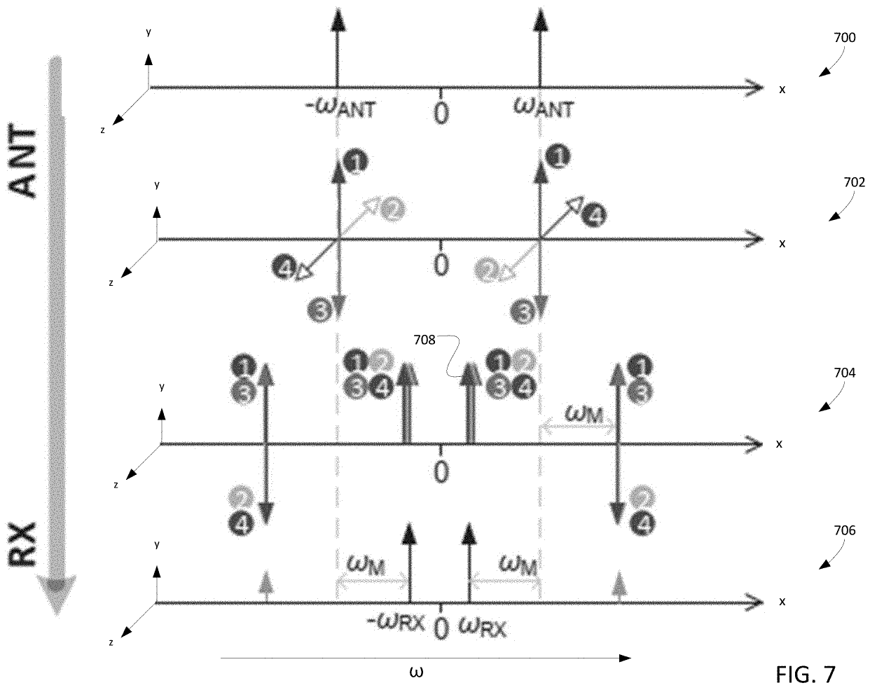

Referring to FIG. 7, a similar analysis can be applied to the RX signal that is received at the antenna port 402. In FIG. 7, phasor diagrams 700, 702, 704, and 706 are shown having an x-axis representing frequency, a y-axis representing the real portion of the phasors, and a z-axis representing the imaginary portion of the phasors. Plot 700 illustrates the first stage where the signal having a frequency ω_{ANT} is at the antenna port 402. The signal then proceeds to flow through the phase shift circuits 408a-d to produce phase-shifted signals having real and imaginary components as shown in plot 702. The phase shifted signal in plot 702 is then modulated by the modulation switches 410a-d, resulting in the phasors 708 for the modulated signal shown (stacked on top of each other) along the real axis in plot 704. After modulation, the signal will have components at frequencies ω_{ANT}−ω_{M} (e.g. phasors 708) and at ω_{ANT}+ω_{M} (e.g. phasors 710), where ω_{M} is the modulation frequency. In the next stage, the low pass filter 314 rejects the high frequency component at ω_{ANT}+ω_{M} and allows the lower-frequency component at ω_{ANT}−ω_{M} to pass through as the RX signal (having a frequency of about ω_{RX}=ω_{ANT}−ω_{M}.

As shown, the bi-directional frequency converter can separate the RX signal from the TX signal by modulating and shifting the TX signal to a higher frequency, and by modulating and shifting the RX signal to a lower frequency. This allows both signals to be transmitted and received at the same antenna at the same time. Furthermore, the bi-directional frequency converter is less expensive and takes less chip area than a circulator. It also results in reduced coupling between the RX and TX signals within the transceiver device (e.g. mobile device 104).

The embodiments described above include a four-path bi-directional frequency converter circuit where each of the four signal paths shifts the phase of the signal by ϕ_{M}=0°, 90°, 180°, and 270°, respectively. In other embodiments, the bi-directional frequency converter may have more or fewer signal paths, and may shift the phase of the RX and TX signals by different degree values. For example, another design may have eight signal paths, each having a phase shift circuit and a switch, where each signal path shifts the phase of the signal by 0°, 45°, 90°, 135°, 180°, 225°, 270°, and 315°, respectively. Other combinations of the number of signal paths and the degrees of phase shift may also be used.

Additionally, the system described above illustrates an example where the TX signal is shifted to a higher frequency and the RX signal is shifted to a lower frequency. A high pass filter is used to filter the TX signal and a low pass filter is used to filter the RX signal. One skilled in the art will recognize that, in other embodiments, the filtering may be swapped so that the TX signal is shifted to a lower frequency and the RX signal is shifted to a higher frequency.

Also, all though the system above is described as a wireless 5G or 6G IBFD system, the bi-directional frequency converter can be with other wired or wireless architectures.

Various embodiments of the concepts, systems, devices, structures, and techniques sought to be protected are described above with reference to the related drawings. Alternative embodiments can be devised without departing from the scope of the concepts, systems, devices, structures, and techniques described. It is noted that various connections and positional relationships (e.g., over, below, adjacent, etc.) may be used to describe elements in the description and drawing. These connections and/or positional relationships, unless specified otherwise, can be direct or indirect, and the described concepts, systems, devices, structures, and techniques are not intended to be limiting in this respect. Accordingly, a coupling of entities can refer to either a direct or an indirect coupling, and a positional relationship between entities can be a direct or indirect positional relationship.

As an example of an indirect positional relationship, positioning element “A” over element “B” can include situations in which one or more intermediate elements (e.g., element “C”) is between elements “A” and elements “B” as long as the relevant characteristics and functionalities of elements “A” and “B” are not substantially changed by the intermediate element(s).

Also, the following definitions and abbreviations are to be used for the interpretation of the claims and the specification. The terms “comprise,” “comprises,” “comprising, “include,” “includes,” “including,” “has,” “having,” “contains” or “containing,” or any other variation are intended to cover a non-exclusive inclusion. For example, an apparatus, a method, a composition, a mixture or an article, that comprises a list of elements is not necessarily limited to only those elements but can include other elements not expressly listed or inherent to such apparatus, method, composition, mixture, or article.

Additionally, the term “exemplary” is means “serving as an example, instance, or illustration. Any embodiment or design described as “exemplary” is not necessarily to be construed as preferred or advantageous over other embodiments or designs. The terms “one or more” and “at least one” indicate any integer number greater than or equal to one, i.e. one, two, three, four, etc. The term “plurality” indicates any integer number greater than one. The term “connection” can include an indirect “connection” and a direct “connection”.

References in the specification to “embodiments,” “one embodiment, “an embodiment,” “an example embodiment,” “an example,” “an instance,” “an aspect,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it may affect such feature, structure, or characteristic in other embodiments whether or not explicitly described.

Relative or positional terms including, but not limited to, the terms “upper,” “lower,” “right,” “left,” “vertical,” “horizontal, “top,” “bottom,” and derivatives of those terms relate to the described structures and methods as oriented in the drawing figures. The terms “overlying,” “atop,” “on top, “positioned on” or “positioned atop” mean that a first element, such as a first structure, is present on a second element, such as a second structure, where intervening elements such as an interface structure can be present between the first element and the second element. The term “direct contact” means that a first element, such as a first structure, and a second element, such as a second structure, are connected without any intermediary elements.

Use of ordinal terms such as “first,” “second,” “third,” etc., in the claims to modify a claim element does not by itself connote any priority, precedence, or order of one claim element over another, or a temporal order in which acts of a method are performed, but are used merely as labels to distinguish one claim element having a certain name from another element having a same name (but for use of the ordinal term) to distinguish the claim elements.

The terms “approximately” and “about” may be used to mean within ±20% of a target value in some embodiments, within ±10% of a target value in some embodiments, within ±5% of a target value in some embodiments, and yet within ±2% of a target value in some embodiments. The terms “approximately” and “about” may include the target value. The term “substantially equal” may be used to refer to values that are within ±20% of one another in some embodiments, within ±10% of one another in some embodiments, within ±5% of one another in some embodiments, and yet within ±2% of one another in some embodiments.

The term “substantially” may be used to refer to values that are within ±20% of a comparative measure in some embodiments, within ±10% in some embodiments, within ±5% in some embodiments, and yet within ±2% in some embodiments. For example, a first direction that is “substantially” perpendicular to a second direction may refer to a first direction that is within ±20% of making a 90° angle with the second direction in some embodiments, within ±10% of making a 90° angle with the second direction in some embodiments, within ±5% of making a 90° angle with the second direction in some embodiments, and yet within ±2% of making a 90° angle with the second direction in some embodiments.

The disclosed subject matter is not limited in its application to the details of construction and to the arrangements of the components set forth in the following description or illustrated in the drawings. The disclosed subject matter is capable of other embodiments and of being practiced and carried out in various ways.

Also, the phraseology and terminology used in this patent are for the purpose of description and should not be regarded as limiting. As such, the conception upon which this disclosure is based may readily be utilized as a basis for the designing of other structures, methods, and systems for carrying out the several purposes of the disclosed subject matter. Therefore, the claims should be regarded as including such equivalent constructions insofar as they do not depart from the spirit and scope of the disclosed subject matter.

Although the disclosed subject matter has been described and illustrated in the foregoing exemplary embodiments, the present disclosure has been made only by way of example. Thus, numerous changes in the details of implementation of the disclosed subject matter may be made without departing from the spirit and scope of the disclosed subject matter.

Accordingly, the scope of this patent should not be limited to the described implementations but rather should be limited only by the spirit and scope of the following claims.

All publications and references cited in this patent are expressly incorporated by reference in their entirety.

1. A transceiver system comprising:
an antenna;
a transmit/receive (TX/RX) circuit configured to couple transmit (TX) signals for transmission to the antenna and receive incoming (RX) signals from the antenna, wherein transmission of the TX signals and reception of the RX signals occurs concurrently within a single frequency band; and
a bidirectional frequency converter (BDFC) circuit to separate the TX signals from the RX signals by converting the frequency of the TX signals, the RX signals, or both.

2. The transceiver system of claim 1 wherein the BDFC circuit is configured to shift the frequency of the RX signal in one direction in a frequency spectrum and shift the frequency of the TX signal in another direction in the frequency spectrum.

3. The transceiver of claim 2 wherein the frequency converter circuit is configured to shift the frequency of the RX signal to a relatively lower frequency and shift the frequency of the TX signal a relatively higher frequency.

4. The transceiver system of claim 1 further comprising a first filter to filter the TX signals and a second filter to filter the RX signals.

5. The transceiver system of claim 1 wherein the BDFC circuit comprises a plurality of parallel signal paths.

6. The transceiver system of claim 1 wherein the BDFC circuit comprises four signal paths.

7. The transceiver system of claim 5 wherein at least one of the plurality of parallel signal paths includes a phase shift circuit.

8. The transceiver system of claim 5 wherein at least one of the plurality of parallel signal paths includes a switch for modulating the TX signal and/or modulating the RX signal.

9. The transceiver system of claim 5 wherein multiple paths of the plurality of parallel signal paths includes a phase shift circuit and each phase shift circuit is configured to shift the phase of the TX signal and/or the RX signal by a different degree value.

10. The transceiver system of claim 5 wherein the plurality of parallel signal paths are differential signal paths.

11. The transceiver system of claim 10 wherein at least one of the plurality of parallel signal paths includes a differential modulation switch and a differential phase shift circuit.

12. A transceiver system comprising:
an antenna;
a transmit/receive (TX/RX) circuit configured to couple transmit (TX) signals for transmission to the antenna and receive incoming (RX) signals from the antenna, wherein transmission of the TX signals and reception of the RX signals occurs concurrently within a single frequency band; and
a bidirectional frequency converter (BDFC) circuit having:
one or more signal paths that convert a frequency of the TX signals to a first frequency and convert a frequency of the RX signals second frequency, wherein the first frequency and the second frequency are in separate frequency bands;
a first port coupled to the antenna and configured to receive the RX signals and transmit the TX signals within the single frequency band; and
a second port coupled to the message circuit to:
receive the TX signals having the first frequency from the message circuit; and
transmit the RX signals having the second frequency to the messaging circuit.

13. The transceiver system of claim 12 wherein the BDFC circuit is configured to shift the frequency of the RX signal to a relatively lower frequency in a frequency spectrum and shift the frequency of the TX signal a relatively higher frequency in the frequency spectrum.

14. The transceiver system of claim 12 further comprising a first filter to pass the TX signals having the first frequency and a second filter to pass the RX signals having the second frequency.

15. The transceiver system of claim 12 wherein the BDFC circuit comprises four signal paths.

16. The transceiver system of claim 12 wherein at least one of the parallel signal paths includes a phase shift circuit.

17. The transceiver system of claim 12 wherein at least one of the plurality of parallel signal paths includes a switch for modulating the TX signal and/or modulating the RX signal.

18. The transceiver system of claim 12 wherein the one or more parallel signal paths are differential signal paths.

19. The transceiver system of claim 18 wherein at least one of the plurality of parallel signal paths includes a differential modulation switch and a differential phase shift circuit.

20. A transceiver system comprising:
an antenna;
a transmit/receive (TX/RX) circuit configured to couple transmit (TX) signals for transmission to the antenna and receive incoming (RX) signals from the antenna, wherein transmission of the TX signals and reception of the RX signals occurs concurrently within a single frequency band; and
means for modulating the TX signal and the RX signal by a modulation frequency; and
means for shifting a frequency of the TX signal to a first frequency and shifting the RX signal to a second frequency, wherein the first and second frequencies are in different frequency bands.
